(19) United States
(12) Patent Application Publication
(10) Pub. No.: US 2024/0210838 A1
(43) Pub. Date: Jun. 27, 2024

(54) METHOD OF DESIGNING MASK LAYOUT FOR IMAGE SENSOR

(71) Applicant: Samsung Electronics Co., Ltd., Suwon-si (KR)

(72) Inventors: Yujeong SIN, Suwon-si (KR); Daehyun JUNG, Suwon-si (KR); Sunggon JUNG, Suwon-si (KR)

(73) Assignee: Samsung Electronics Co., Ltd., Suwon-si (KR)

(21) Appl. No.: 18/473,635

(22) Filed: Sep. 25, 2023

(30) Foreign Application Priority Data
Dec. 22, 2022 (KR) 10-2022-0182186

(51) Int. Cl. G03F 7/00

(52) U.S. Cl. CPC G03F 7/705; G03F 7/70441

(57) ABSTRACT

A mask layout design method includes designing a preliminary mask layout, designing a plurality of target mask layouts by inserting a plurality of preliminary assist patterns into the preliminary mask layout, generating an optical proximity correction (OPC) model based on the plurality of target mask layouts, obtaining a plurality of mask design images by using the OPC model, extracting a plurality of mask contour images, selecting a plurality of target patterns, producing a mask based on the plurality of target mask layouts, forming a real pattern on a substrate based on the mask, and selecting a final pattern from among the plurality of target patterns based on the formed real pattern. The preliminary mask layout includes a mask layout defining a pixel isolation structure that isolates a plurality of pixels, and the preliminary assist pattern has at least one of a cross or rectangular shape.

### CROSS-REFERENCE TO RELATED APPLICATION

This application is based on and claims priority under 35 U.S.C. § 119 to Korean Patent Application No. 10-2022-0182186, filed on Dec. 22, 2022, in the Korean Intellectual Property Office, the disclosure of which is incorporated by reference herein in its entirety.

### BACKGROUND

Various example embodiments relate to a mask layout design method, and more particularly, to a method of designing a mask layout for a pixel isolation structure of an image sensor.

In a semiconductor process, a photolithography process using a photomask (or a mask) may be performed to form a pattern on a semiconductor substrate, such as a wafer. The mask may be simply referred to as a pattern transfer body having an opaque pattern shape formed on a transparent base layer material. A mask manufacturing process is described as follows: designing a specific circuit; designing a layout of the circuit; and then transferring, as mask tape-out (MTO) design data, mask design data obtained through optical proximity correction (OPC). Thereafter, mask data preparation (MDP) is performed based on the MTO design data, and a mask may be produced by performing an exposure process and the like.

### SUMMARY

Various example embodiments provide a mask layout design method by which an image sensor with improved reliability may be manufactured.

The problems to be solved or improved upon by the technical idea of inventive concepts are not limited to the problem mentioned above, and the other problems could be clearly understood by those of ordinary skill in the art from the description below.

According various example embodiments, there is provided a mask layout design method including designing a preliminary mask layout, designing a plurality of target mask layouts by inserting a plurality of preliminary assist patterns into the preliminary mask layout, generating an optical proximity correction (OPC) model based on the plurality of target mask layouts, and obtaining a plurality of mask design images by performing a simulation using the OPC model. The method further includes extracting a plurality of mask contour images based on the plurality of mask design images, selecting a plurality of target patterns from among the plurality of preliminary assist patterns based on the plurality of mask contour images, producing a mask based on the plurality of target mask layouts including the plurality of target patterns, forming a real pattern on a substrate based on the mask, and selecting a final pattern from among the plurality of target patterns based on the formed real pattern. The preliminary mask layout includes a mask layout defining a pixel isolation structure that isolates a plurality of pixels, and the preliminary assist pattern has at least one of a cross or rectangular shape in plan view.

Alternatively or additionally according to some example embodiments, there is provided a mask layout design method including designing a preliminary mask layout based on a design rule, designing a target mask layout by inserting a first preliminary assist pattern into the preliminary mask layout and inserting a second preliminary assist pattern into the preliminary mask layout, verifying the first preliminary assist pattern by using the target mask layout, producing a mask based on the target mask layout, forming a real pattern on a substrate based on the mask, and verifying the second preliminary assist pattern based on the real pattern. The preliminary mask layout includes a mask layout defining a pixel isolation structure that isolates a plurality of pixels, the first preliminary assist pattern is inserted into a pixel corner region of the preliminary mask layout, and the second preliminary assist pattern is inserted into a central region of the preliminary mask layout.

Alternatively or additionally according to various example embodiments, there is provided a mask layout design method including designing a preliminary mask layout, designing a plurality of target mask layouts by inserting a plurality of preliminary assist patterns into the preliminary mask layout, generating an optical proximity correction (OPC) model based on the plurality of target mask layouts, obtaining a plurality of mask design images by using the OPC model to perform OPC on each of the plurality of target mask layouts, extracting a plurality of mask contour images based on the plurality of mask design images, selecting a plurality of target patterns from among the plurality of preliminary assist patterns based on the plurality of mask contour images, producing a mask based on the plurality of target mask layouts including the plurality of target patterns, forming a real pattern on a substrate based on the mask, and selecting a final pattern from among the plurality of target patterns based on the formed real pattern. The preliminary mask layout includes a mask layout defining a pixel isolation structure that isolates a plurality of pixels, the preliminary assist pattern includes a first preliminary assist pattern and a second preliminary assist pattern, the first preliminary assist pattern is inserted into a pixel corner region of the mask layout, and the second preliminary assist pattern is formed in a central region of the mask layout.

### BRIEF DESCRIPTION OF THE DRAWINGS

Various example embodiments will be more clearly understood from the following detailed description taken in conjunction with the accompanying drawings in which:

FIG. 1 is a block diagram illustrating an image sensor according to some example embodiments;

FIG. 2 is a circuit diagram illustrating pixels included in an image sensor according to some example embodiments;

FIG. 3 is a top view illustrating a plurality of pixel structures and a pixel isolation structure in an image sensor according to some example embodiments;

FIG. 4 is a partial magnified view illustrating a first pixel structure of FIG. 3;

FIG. 5 is a partial magnified view illustrating a central region of FIG. 4;

FIG. 6 is a flowchart illustrating a mask layout design method according to some example embodiments;

FIG. 7 is a top view illustrating a preliminary mask layout in the mask layout design method of FIG. 6;

FIG. 8A is a top view illustrating a target mask layout according to some example embodiments, in the mask layout design method of FIG. 6;

FIGS. 8B and 8C are partial magnified views of the target mask layout of FIG. 8A;

FIG. 9A is a top view illustrating a target mask layout according to another embodiment, in the mask layout design method of FIG. 6;

FIG. 9B is a partial magnified view of the target mask layout of FIG. 9A;

FIGS. 10A and 10B are top views illustrating mask design images according to embodiments, in the mask layout design method of FIG. 6; and

FIG. 11 is a top view illustrating a contour image in the mask layout design method of FIG. 6.

### DETAILED DESCRIPTION OF VARIOUS EXAMPLE EMBODIMENTS

Hereinafter, some example embodiments are described in detail with reference to the accompanying drawings. Like reference numerals in the drawings denote like elements, and thus their repetitive description is omitted.

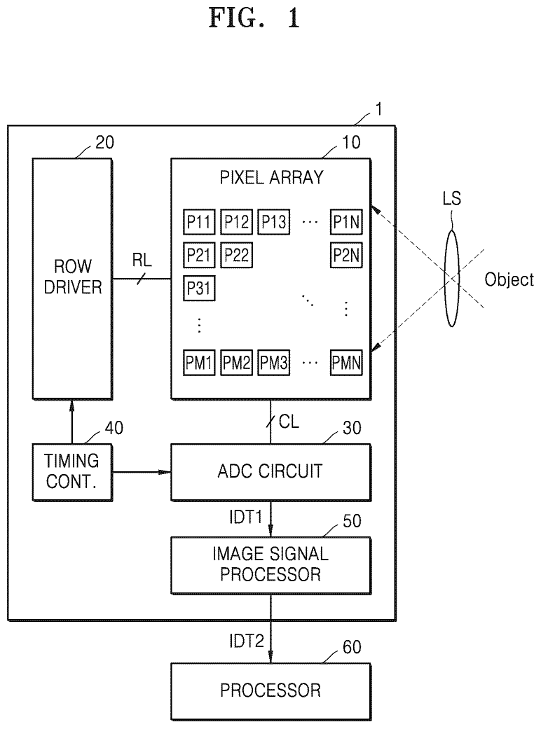

FIG. 1 is a block diagram illustrating an image sensor 1 according to some example embodiments.

Referring to FIG. 1, the image sensor 1 according to some example embodiments may be mounted in an electronic device having an image and/or a light sensing function. For example, the image sensor 1 may be applied to an electronic device, such as one or more of a camera, a smartphone, a wearable device, Internet of Things (IoT), a tablet personal computer (PC), a personal digital assistant (PDA), a portable multimedia player (PMP), or a navigation device. Alternatively or additionally, the image sensor 1 may be employed to one or more of vehicles, furniture, manufacturing equipment, doors, various kinds of measurement instruments, and the like.

The image sensor 1 may include a pixel array 10, a row driver 20, an analog-digital converter circuit (hereinafter, referred to as an ADC circuit) 30, a timing controller 40, and an image signal processor 50.

The pixel array 10 may receive an optical signal reflected from an object and incident through a lens LS and convert the optical signal into an electrical signal. The pixel array 10 may be implemented by a complementary metal oxide semiconductor (CMOS) image sensor but is not limited thereto. Alternatively or additionally, the pixel array 10 may be or may include a portion of a charge coupled device (CCD) chip.

The pixel array 10 may include a plurality of row lines RL, a plurality of column lines (or output lines) CL, and a plurality of pixels P11, P12, P13, . . . , P1N, P21, P22, . . . , P2N, P31, . . . PM1, PM2, PM3, . . . , and PMN (hereinafter, P11 to PMN) connected to the plurality of row lines RL and the plurality of column lines CL and arranged in M rows (or, wordlines) and N columns (or, bitlines). As described, the number of pixels P11 to PMN may be M×N. In various example embodiments, M may be greater than, equal to, or less than N.

Each of the plurality of pixels P11 to PMN may sense a received optical signal by using a photoelectric conversion device. The plurality of pixels P11 to PMN may detect a light intensity of an optical signal and may output an electrical signal (such as a voltage) indicating the detected light intensity.

The row driver 20 may generate a plurality of control signals for controlling an operation of the plurality of pixels P11 to PMN arranged in respective rows, under control by the timing controller 40. The row driver 20 may provide the plurality of control signals to the plurality of pixels P11 to PMN in respective rows of the pixel array 10 through the plurality of row lines RL. The pixel array 10 may be driven in row units in response to the plurality of control signals provided from the row driver 20.

Under control by the row driver 20, the pixel array 10 may output a plurality of sensing signals through the plurality of column lines CL.

The ADC circuit 30 may perform ADC on each of the plurality of sensing signals received through the plurality of column lines CL. The ADC circuit 30 may include an analog-digital converter (hereinafter, referred to as an ADC) corresponding to each of the plurality of column lines CL, and the ADC may convert a sensing signal received through a corresponding column line CL into a pixel value. According to an operation mode of the image sensor 1, a pixel value may indicate a light intensity sensed by the plurality of pixels P11 to PMN.

The ADC may include a correlated double sampling (CDS) circuit (not shown) configured to sample and hold a received signal. The CDS circuit may double-sample a noise signal and a sensing signal in a reset state of the plurality of pixels P11 to PMN and output a signal corresponding to a difference between the sensing signal and the noise signal. The ADC may include a counter, and the counter may generate a pixel value by counting a signal received from the CDS circuit. For example, the CDS circuit may be implemented by one or more of an operational transconductance amplifier (OTA), a differential amplifier, or the like. The counter may be implemented by, for example, one or more of an up-counter and an operational circuit, an up/down counter and a bit-wise inversion counter, or the like.

The timing controller 40 may generate timing control signals for controlling operations of the row driver 20 and the ADC circuit 30. As described above based on the timing control signals from the timing controller 40, the row driver 20 and the ADC circuit 30 may drive the pixel array 10 in row units and also may convert the plurality of sensing signals received through the plurality of column lines CL into pixel values.

The image signal processor 50 may receive first image data IDT1, e.g., non-processed image data, from the ADC circuit 30 and perform signal processing on the first image data IDT1. The image signal processor 50 may perform signal processing, such as black level compensation, lens shading compensation, crosstalk compensation, and bad pixel correction.

Second image data IDT2, e.g., signal-processed image data, output from the image signal processor 50 may be transmitted to a processor 60. The processor 60 may be a host processor of an electronic device in which the image sensor 1 is mounted.

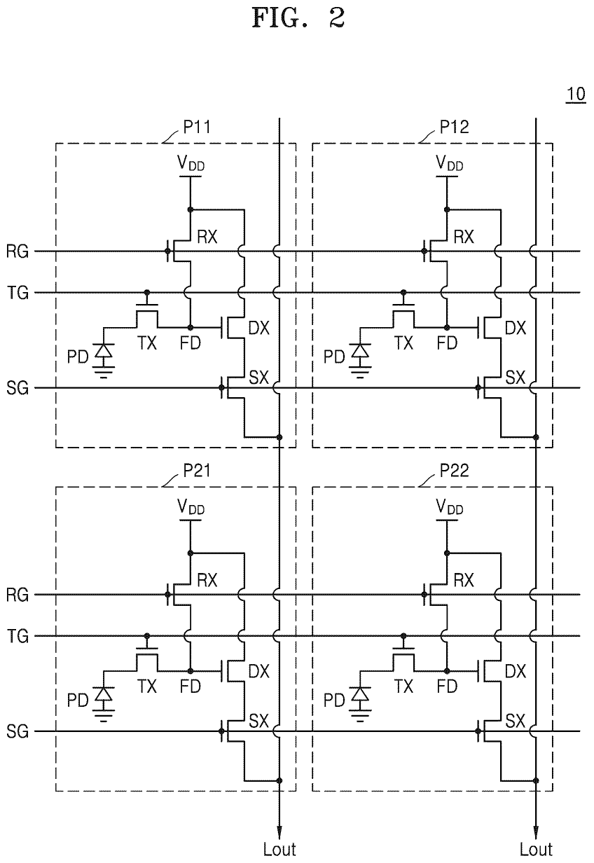

FIG. 2 is a circuit diagram illustrating pixels included in an image sensor according to some example embodiments.

Referring to FIGS. 1 and 2, the pixel array 10 may include pixels P11, P12, P21, and P22. The pixels P11, P12, P21, and P22 may be arranged in a matrix form, such as a rectangular (or square) form of M rows and N columns. Although FIG. 2 shows only four pixels P11, P12, P21, and P22 for convenience of drawing, a description of the pixels P11, P12, P21, and P22 may be similarly applied to each of the plurality of pixels P11 to PMN included in the pixel array 10.

According to various example embodiments, each of the pixels P11, P12, P21, and P22 may include a transfer transistor TX and logic transistors RX, SX, and DX. Herein, the logic transistors RX, SX, and DX may include a reset transistor RX, a select transistor SX, and a drive transistor DX. Each transistor may be NMOS transistors; however, example embodiments are not limited thereto. Furthermore each transistor may have the same electrical properties, such as the same threshold voltage and/or the same drive current; however, example embodiments are not limited thereto. Alternatively or additionally each transistor may have the same geometric properties such as the same channel width and/or the same oxide thickness; however, example embodiments are not limited thereto.

A photoelectric conversion device PD may generate and accumulate photo-charges in proportion to the amount of light incident from the outside. The photoelectric conversion device PD may be or may include or be included in a photo-sensing device including an organic material or an inorganic material, such as one or more of an inorganic photodiode, an organic photodiode, a perovskite photodiode, a photo-transistor, a photo-gate, a pinned photodiode, or an organic photoconductive film.

The transfer transistor TX may transfer photo-charges accumulated in the photoelectric conversion device PD to a floating diffusion region FD based on a transfer signal TG. The photo-charges generated by the photoelectric conversion device PD may be stored in the floating diffusion region FD. The drive transistor DX may be controlled by the amount of photo-charges accumulated in the floating diffusion region FD.

The reset transistor RX may periodically reset the photo-charges accumulated in the floating diffusion region FD, based on a reset signal RG. A drain electrode of the reset transistor RX may be connected to the floating diffusion region FD, and a source electrode thereof may be connected to a power source voltage VDD. When the reset transistor RX is turned on, the power source voltage VDD connected to the source electrode of the reset transistor RX may be transferred to the floating diffusion region FD. Therefore, when the reset transistor RX is turned on, the photo-charges accumulated in the floating diffusion region FD may be discharged, thereby resetting the floating diffusion region FD.

The drive transistor DX in each of the pixels P11, P12, P21, and P22 may form a source follower buffer amplifier together with a constant current source outside to so as to amplify a potential change in the floating diffusion region FD and output the amplified potential change to an output line Lout.

The select transistor SX may select the pixels P11, P12, P21, and P22 to read a sensed photoelectric signal value in a row unit, based on a select signal SG. When the select transistor SX is turned on, the power source voltage VDD may be transferred to a source electrode of the drive transistor DX.

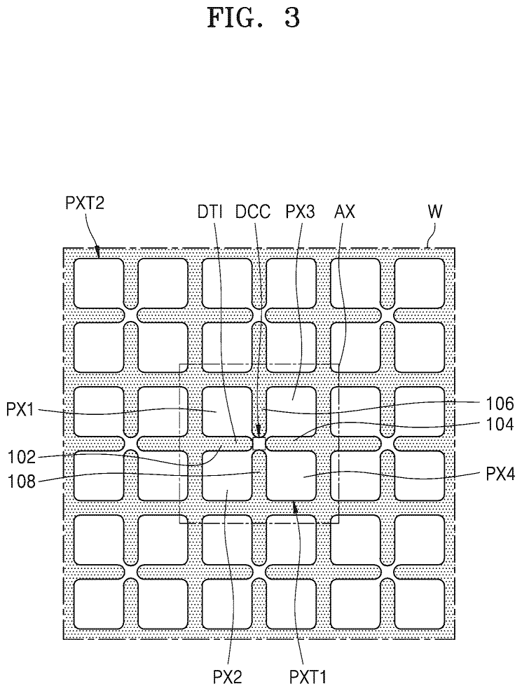

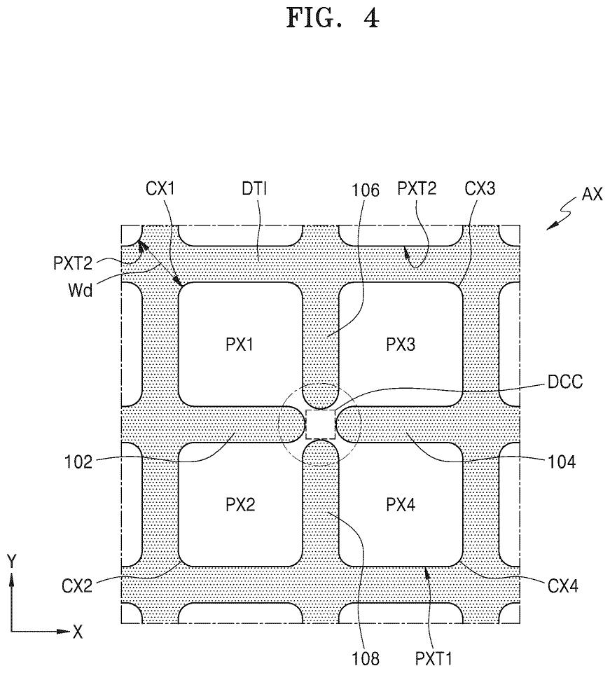

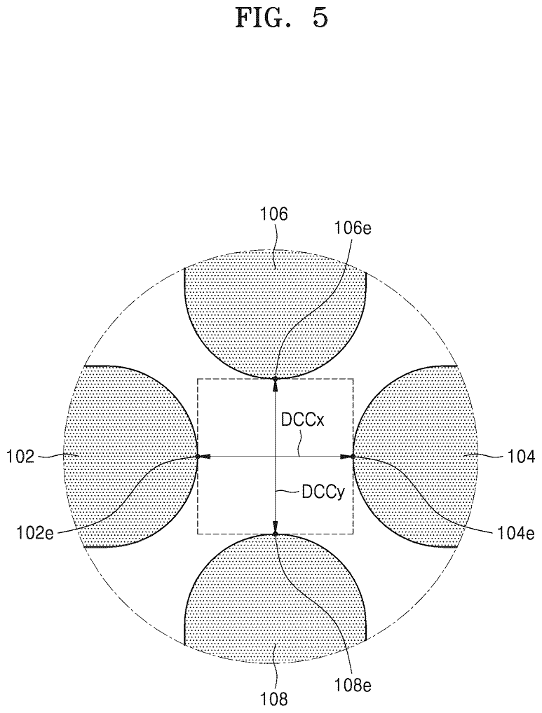

FIG. 3 is a top view illustrating a plurality of pixel structures and a pixel isolation structure DTI in an image sensor according to some example embodiments. FIG. 4 is a partial magnified view illustrating a first pixel structure PXT1 of FIG. 3. FIG. 5 is a partial magnified view illustrating a central region DCC of FIG. 4. Hereinafter, a description is made with reference to FIG. 1 together, and some descriptions made with reference to FIG. 1 are simply repeated or omitted.

Referring to FIG. 3, the image sensor 1 may include a substrate W, the plurality of pixel structures PXT, and the pixel isolation structure DTI. The plurality of pixel structures PXT and the pixel isolation structure DTI may be on the substrate W.

The plurality of pixel structures PXT may be disposed in a matrix form on the substrate W. The plurality of pixel structures PXT may be separated by a constant distance from each other. A pixel structure PXT may include at least four pixels. For example, the pixel structure PXT may include a first pixel PX1, a second pixel PX2, a third pixel PX3, and a fourth pixel PX4.

The pixel isolation structure DTI may define and isolate the plurality of pixel structures PXT from each other. In addition, the pixel isolation structure DTI may extend inside the pixel structure PXT. The pixel isolation structure DTI may be in a separated space of the plurality of pixel structures PXT and insulate the plurality of pixel structures PXT from each other. In some example embodiments, the pixel isolation structure DTI may isolate the first pixel PX1, the second pixel PX2, the third pixel PX3, and the fourth pixel PX4 in the pixel structure PXT from each other. The pixel isolation structure DTI may insulate the first pixel PX1, the second pixel PX2, the third pixel PX3, and the fourth pixel PX4 in one pixel structure PXT from each other. The pixel isolation structure DTI may include an insulating material such as but not limited to silicon oxide.

For example, the pixel isolation structure DTI may include a first protruding portion 102, a second protruding portion 104, a third protruding portion 106, and a fourth protruding portion 108 each extending inside the pixel structure PXT. The first through fourth protruding portions 102, 104, 106, and 108 may protrude in a horizontal direction (e.g., in one or the X direction or the Y direction).

Referring to FIGS. 4 and 5, the first pixel structure PXT1 may include the central region DCC and a plurality of corner portions CX1, CX2, CX3, CX4. The central region DCC of the first pixel structure PXT1 may be or may correspond to a central portion of the first pixel PX1, the second pixel PX2, the third pixel PX3, and the fourth pixel PX4.

The first pixel structure PXT1 may have a structure in which the first pixel PX1, the second pixel PX2, the third pixel PX3, and the fourth pixel PX4 share the central region DCC. The first pixel PX1, the second pixel PX2, the third pixel PX3, and the fourth pixel PX4 may be at an outer side in a radial direction with the central region DCC at the center thereof so as to surround the central region DCC. In some example embodiments, a floating diffusion region (see FD of FIG. 2) may be formed in the central region DCC.

Although FIGS. 3 to 5 show that the central region DCC of the first pixel structure PXT1 has a quadrangular shape, the central region DCC is not limited thereto, and the central region DCC of the first pixel structure PXT1 may be curved and/or polygonal, e.g. may have a shape of any one of a square, a beveled or chamfered square, a rectangle, a beveled or chamfered rectangle, and a circle. The central region DCC of the first pixel structure PXT1 may be or may include or be included in a region connecting the first pixel PX1, the second pixel PX2, the third pixel PX3, and the fourth pixel PX4 to each other. For example, the central region DCC of the first pixel structure PXT1 may be defined by the pixel isolation structure DTI. In some example embodiments, the central region DCC may be defined by respective distal ends, e.g., first to fourth ends 102e, 104e, 106e, and 108e, of the first protruding portion 102, the second protruding portion 104, the third protruding portion 106, and the fourth protruding portion 108.

A horizontal width DCCx of the central region DCC may be defined by a separation distance between the first end 102e of the first protruding portion 102 and the second end 104e of the second protruding portion 104. In addition, a vertical width DCCy of the central region DCC may be defined by a separation distance between the third end 106e of the third protruding portion 106 and the fourth end 108e of the fourth protruding portion 108. The horizontal width DCCx may be the same as, greater than, or less than the vertical width DCCy.

Corner portions CX1, CX2, CX3, CX4 of the first pixel structure PXT1 may include a first corner CX1, a second corner CX2, a third corner CX3, and a fourth corner CX4. The corner portion CX of the first pixel structure PXT1 may correspond to the corners of the first pixel structure PXT1. In addition, the first corner CX1 may include any one of the corners of the first pixel PX1. The second corner CX2 may include any one of the corners of the second pixel PX2. The third corner CX3 may include any one of the corners of the third pixel PX3. In addition, the fourth corner CX4 may include any one of the corners of the fourth pixel PX4. The corner portion CX of the first pixel structure PXT1 may be defined by the pixel isolation structure DTI surrounding the first pixel structure PXT1.

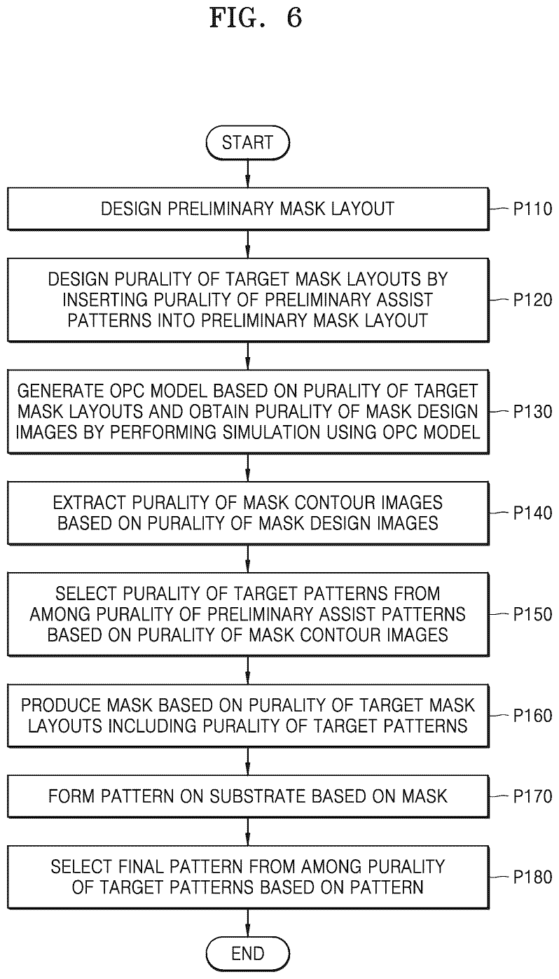

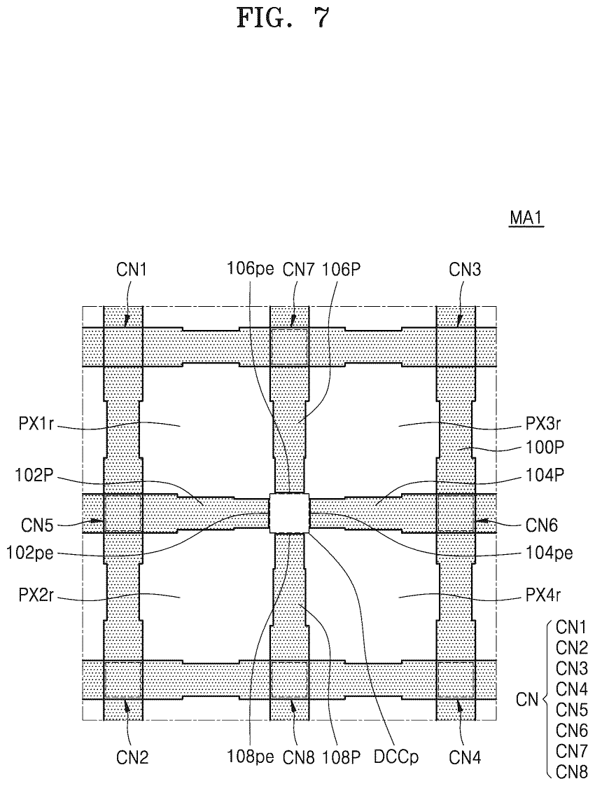

FIG. 6 is a flowchart illustrating a mask layout design method according to some example embodiments. FIG. 7 is a top view illustrating a preliminary mask layout MA1 in the mask layout design method of FIG. 6.

Referring to FIGS. 6 and 7, in the mask layout design method according to various example embodiments, the preliminary mask layout MA1 may be designed in operation P110. The preliminary mask layout design may be performed based on a design rule. The design rule may define a plurality of rules based on a process of producing a pixel isolation structure. For example, the design rule may define one or more of a pitch of patterns, a space between the patterns, and the like, which are allowed in the pixel isolation structure.

A pattern on a substrate may be formed by transferring a pattern that is on a mask to the substrate in an exposure process such as but not limited to a photolithography and etching process. Accordingly, a layout of the pattern on the mask, e.g., a mask layout, corresponding to the pattern on the substrate may be designed. Herein, the preliminary mask layout MA1 may be a mask layout for a pattern of a pixel isolation structure (see DTI of FIG. 4).

The preliminary mask layout MA1 may include a pixel isolation structure pattern 100P. The pixel isolation structure pattern 100P may define a first pixel region PX1r, a second pixel region PX2r, a third pixel region PX3r, and a fourth pixel region PX4r. The pixel isolation structure pattern 100P may include a first protruding pattern 102P protruding between the first pixel region PX1r and the second pixel region PX2r. The pixel isolation structure pattern 100P may include a second protruding pattern 104P protruding between the third pixel region PX3r and the fourth pixel region PX4r. The pixel isolation structure pattern 100P may include a third protruding pattern 106P protruding between the first pixel region PX1r and the third pixel region PX3r. The pixel isolation structure pattern 100P may include a fourth protruding pattern 108P protruding between the second pixel region PX2r and the fourth pixel region PX4r.

By forming the first protruding pattern 102P, the second protruding pattern 104P, the third protruding pattern 106P, and the fourth protruding pattern 108P in the preliminary mask layout MA1, the first pixel region PX1r, the second pixel region PX2r, the third pixel region PX3r, and the fourth pixel region PX4r may be isolated from each other. Additionally or alternatively, by forming the first protruding pattern 102P, the second protruding pattern 104P, the third protruding pattern 106P, and the fourth protruding pattern 108P in the preliminary mask layout MA1, a central region DCCp of the first pixel region PX1r, the second pixel region PX2r, the third pixel region PX3r, and the fourth pixel region PX4r may be formed. The central region DCCp may be defined by a first end 102pe of the first protruding pattern 102P, a second end 104pe of the second protruding pattern 104P, a third end 106pe of the third protruding pattern 106P, and a fourth end 108pe of the fourth protruding pattern 108P. Herein, the central region DCCp may have an optimal size required to connect a plurality of pixels to be formed thereafter.

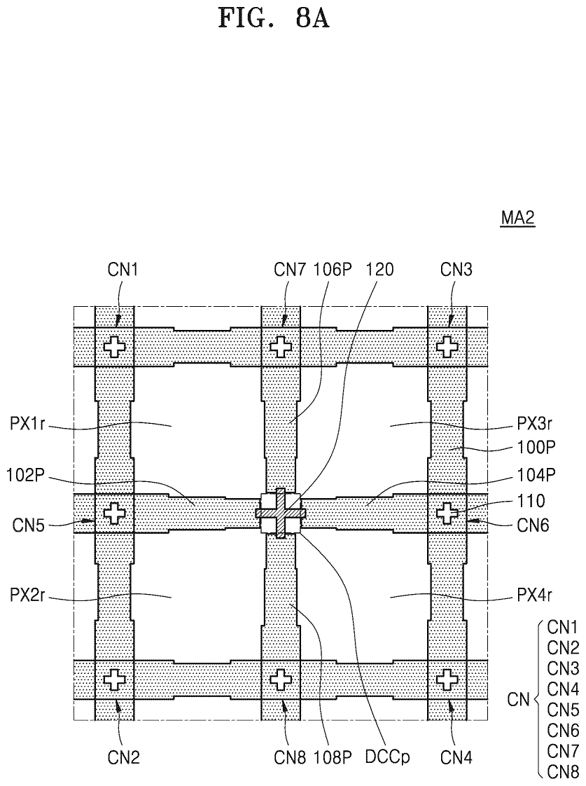

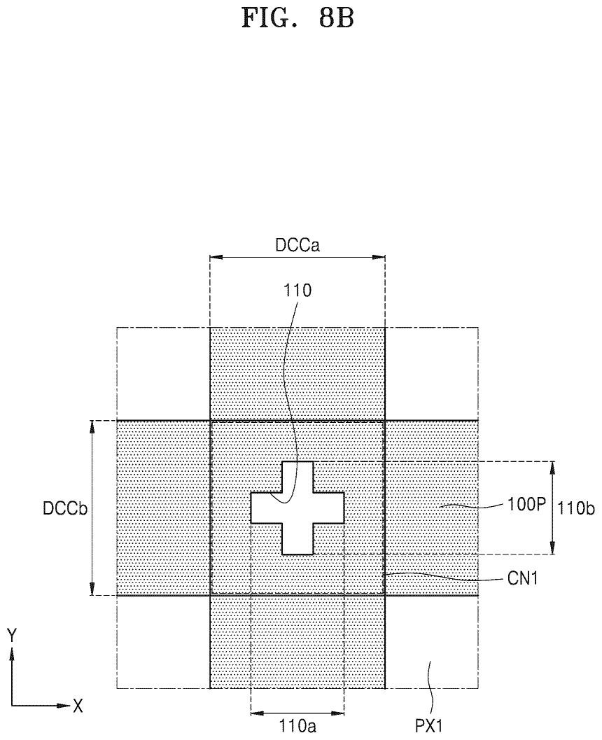

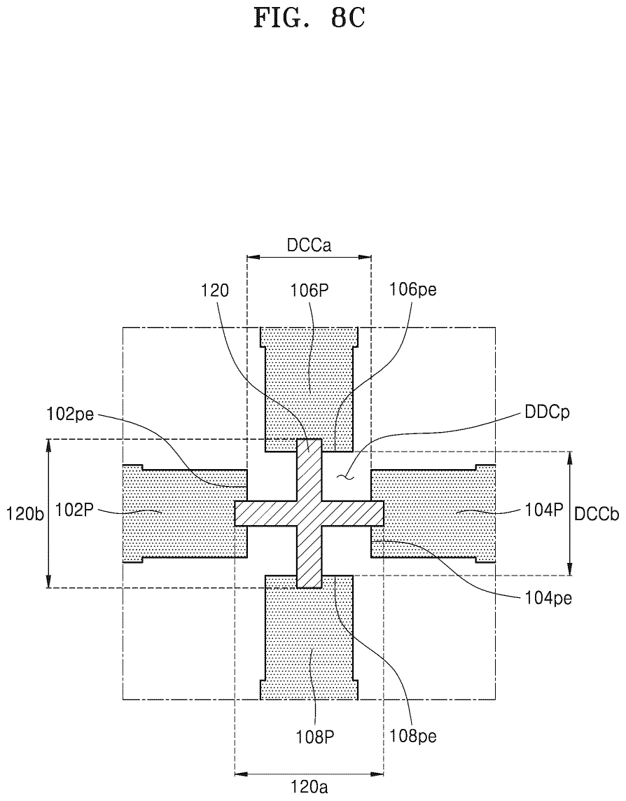

FIG. 8A is a top view illustrating a target mask layout MA2 according to some example embodiments, in the mask layout design method of FIG. 6. FIGS. 8B and 8C are partial magnified views of the target mask layout MA2 of FIG. 8A. Hereinafter, a description is made with reference to FIG. 6 together.

Referring to FIGS. 6 and 8A, after designing the preliminary mask layout (see MA1 of FIG. 7), a plurality of target mask layouts MA2 may be designed by inserting a plurality of preliminary assist patterns into the preliminary mask layout (see MA1 of FIG. 7) in operation P120. The plurality of target mask layouts MA2 may be respectively designed by changing sizes of the plurality of preliminary assist patterns.

The plurality of preliminary assist patterns may include a first preliminary assist pattern 110 and a second preliminary assist pattern 120. The first preliminary assist pattern 110 may have a different tone than the second preliminary assist pattern. For example, in some example embodiments, the first preliminary assist pattern 110 may be a negative pattern, while the second preliminary assist pattern 120 may be a positive pattern; example embodiments are not limited thereto. Additionally or alternatively, each of or at least one of the first and second preliminary assist patterns 110 and 120 may have feature sizes that are smaller than the resolution features of a photolithography process used to pattern the pixel isolation structure DTI, and may, e.g., assist in the patterning of the pixel isolation structure DTI, for example by constructively and/or destructively assisting in the photolithographic processes.

In some example embodiments, a set of eight first preliminary assist patterns 110 and one second preliminary assist pattern 120 may be inserted into the preliminary mask layout (see MA1 of FIG. 7); the eight first preliminary assist patterns 110 may be arranged in a Moore neighborhood around the second preliminary assist pattern 120. The first preliminary assist pattern 110 may be inserted into or arranged in a pixel corner region CN of the pixel isolation structure pattern 100P. The pixel corner region CN may include a first pixel corner region CN1, a second pixel corner region CN2, a third pixel corner region CN3, a fourth pixel corner region CN4, a fifth pixel corner region CN5, a sixth pixel corner region CN6, a seventh pixel corner region CN7, and an eighth pixel corner region CN8. The pixel corner region CN may indicate regions adjacent to corners of the first to fourth pixel regions PX1r, PX2r, PX3r, and PX4r except for the central region DCCp. The pixel corner region CN may have a rectangular (or beveled or chamfered rectangular) or square (or beveled or chamfered square) shape connecting respective corners of the first to fourth pixel regions PX1r, PX2r, PX3r, and PX4r and other pixel regions. The pixel corner region CN may have a shape of connecting corners of most adjacent four pixels.

Referring to FIGS. 8A and 8B, the first preliminary assist pattern 110 may have a cross shape. A size of the first preliminary assist pattern 110 may be less than a size of the second preliminary assist pattern 120. At least eight first preliminary assist patterns 110 may be inserted into the preliminary mask layout (see MA1 of FIG. 7). The size of the first preliminary assist pattern 110 may be less than a size of the pixel corner region CN. Alternatively or additionally, the first preliminary assist pattern 110 may be less than a resolution associated with a photolithographic process used to form the pixel isolation structure DTI, e.g. may have features having a size less than a size of features in a sub-resolution assist feature (SRAF) pattern. The first preliminary assist pattern 110 may have a hole shape in the preliminary mask layout (see MA1 of FIG. 7). A width of the first preliminary assist pattern 110 in a horizontal direction (e.g., an X-axis direction) may be less than a width of the pixel corner region CN in the horizontal direction. A width of the first preliminary assist pattern 110 in a vertical direction (e.g., a Y-axis direction) may be less than a width of the pixel corner region CN in the vertical direction.

Referring to FIGS. 8A and 8C, the second preliminary assist pattern 120 may have a cross shape; horizontal legs on the cross may be greater than, equal to, or less than vertical legs on the cross. The second preliminary assist pattern 120 may have a greater size than the central region DDCp. For example, a horizontal width 120a of the second preliminary assist pattern 120 may be greater than a horizontal width DCCa of the central region DCCp. A vertical width 120b of the second preliminary assist pattern 120 may be greater than a vertical width DCCb of the central region DCCp. The size of the second preliminary assist pattern 120 may be greater than a size defined in the design rule used in operation P110. A portion of the second preliminary assist pattern 120 may overlap portions of the first protruding pattern 102P, the second protruding pattern 104P, the third protruding pattern 106P, and the fourth protruding pattern 108P.

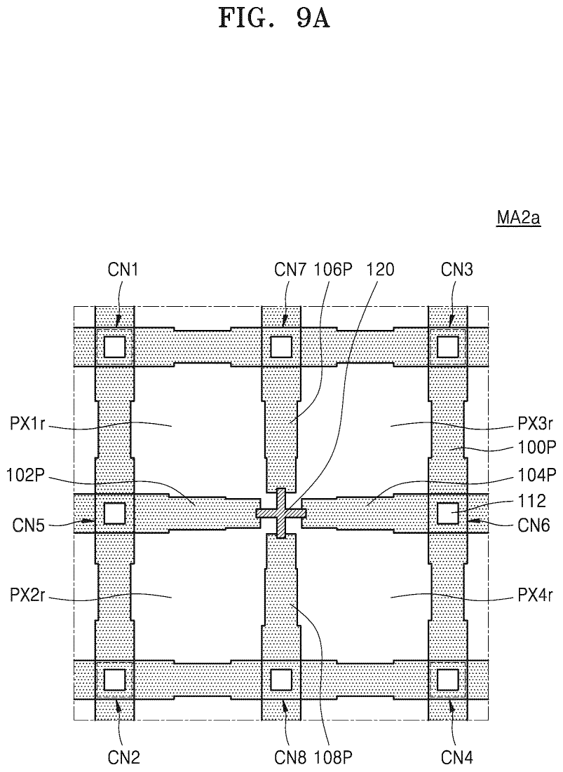

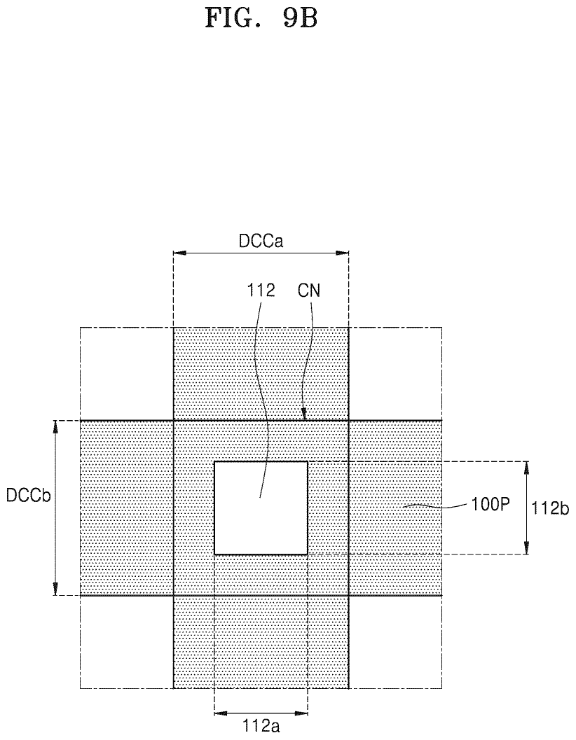

FIG. 9A is a top view illustrating a target mask layout MA2a according to another embodiment, in the mask layout design method of FIG. 6. FIG. 9B is a partial magnified view of the target mask layout MA2a of FIG. 9A. Hereinafter, a description is made with reference to FIG. 6 together, and differences from FIGS. 8A to 8C are mainly described.

Referring to FIGS. 6, 9A, and 9B, according to some example embodiments, a plurality of target mask layouts MA2a may be designed by inserting a plurality of preliminary assist patterns into the preliminary mask layout (see MA1 of FIG. 7) in operation P120. The plurality of preliminary assist patterns may include a first preliminary assist pattern 112 and the second preliminary assist pattern 120. The first preliminary assist pattern 112 may have a square or rectangular shape. The first preliminary assist pattern 112 may be inserted, in a hole shape, into the preliminary mask layout (see MA1 of FIG. 7).

A size of the first preliminary assist pattern 112 may be less than the size of the pixel corner region CN. A width of the first preliminary assist pattern 112 in the horizontal direction (e.g., the X-axis direction) may be less than the width of the pixel corner region CN in the horizontal direction. A width of the first preliminary assist pattern 112 in the vertical direction (e.g., the Y-axis direction) may be less than the width of the pixel corner region CN in the vertical direction.

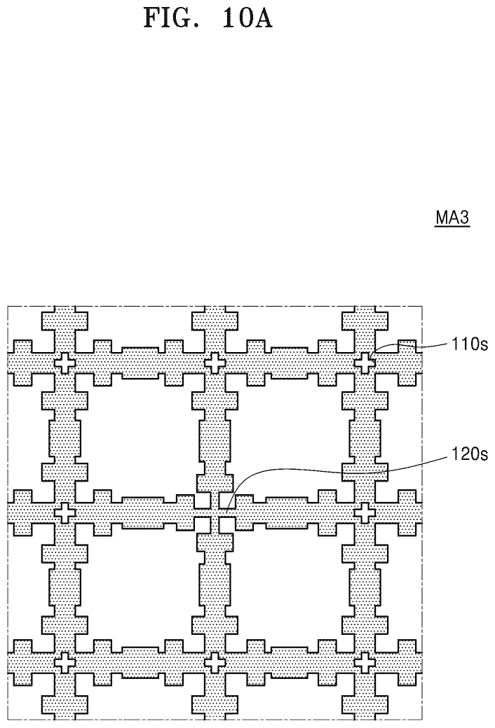

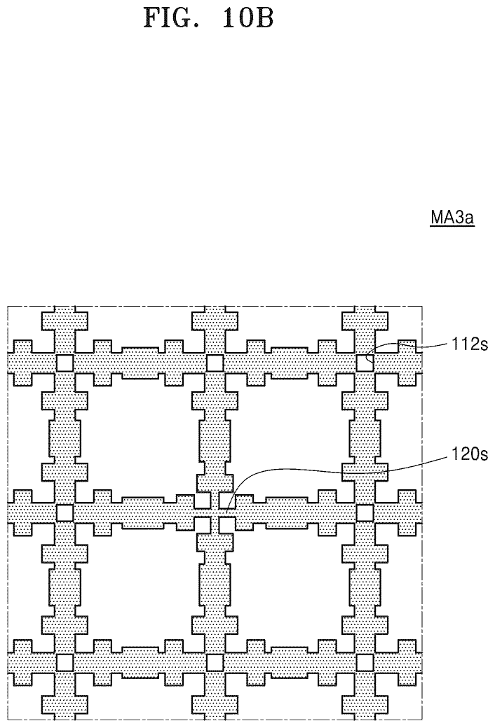

FIGS. 10A and 10B are top views illustrating mask design images MA3 and MA3a according to various example embodiments, in the mask layout design method of FIG. 6. Hereinafter, a description is made with reference to FIG. 6 together.

Referring to FIGS. 6 and 10A, after designing the plurality of target mask layouts, in operation P130, an optical proximity correction (OPC) model may be generated based on the plurality of target mask layouts (e.g., MA2a of FIG. 9), and a plurality of mask design images MA3 may be obtained by performing a simulation using the OPC model.

OPC is generally described as below. The OPC may be largely divided into two types, wherein one thereof is rule-based OPC, and the other one thereof is model-based OPC. The OPC in the mask layout design method according to various example embodiments may be or may include, for example, the model-based OPC. The OPC may include a method of not only changing a shape of a mask layout but also adding sub-lithographic features called serifs at corners of a pattern or a method of adding SRAFs, such as scattering bars.

In the OPC, basic data for the OPC may be prepared. Herein, the basic data may include data of shapes of sample patterns, positions of patterns, a type of measurement, such as measurement of a space or a line of a pattern, and a basic measurement value. In addition, the basic data may include information about one or more of a thickness, a refractive index, a dielectric constant, and the like of a photoresist (PR), and a source map for a shape of an illumination system. Of course, the basic data is not limited to the data described above.

After preparing the basic data, an optical OPC model may be generated. The generation of the optical OPC model may include improving or optimizing a defocus stand (DS) position, a best focus (BF) position, and the like in an exposure process. Alternatively or additionally, the generation of the optical OPC model may include generating an optical image or the like by considering a diffraction phenomenon of light or an optical state of exposure equipment. The generation of the optical OPC model is not limited to those described above. For example, the generation of the optical OPC model may include various operations related to an optical phenomenon in an exposure process.

After generating the optical OPC model, an OPC model for the PR may be generated. The generation of the OPC model for the PR may include improving or optimizing a threshold of the PR. Herein, the threshold of the PR indicates a threshold at which a chemical change occurs in an exposure process, and for example, the threshold may be given as an intensity of exposure light. Alternatively or additionally, the generation of the OPC model for the PR may include selecting a proper model from among various PR model forms.

The optical OPC model and the OPC model for the PR may be combined and called an OPC model. After forming the OPC model, a simulation using the OPC model may be repeated. The simulation may be performed until certain conditions are satisfied. For example, one or more of a root mean square (RMS) for a critical dimension (CD) error, Edge Placement Error (EPE), a reference repetition number, and the like may be used as repetition conditions of the simulation.

In the mask layout design method according to various example embodiments, OPCed layout images or data may be obtained by performing a simulation using the OPC model. The plurality of mask design images MA3 may include the OPCed layout images.

According to some example embodiments, the mask design image MA3, which is OPCed, may be obtained by performing, for a target mask layout (see MA2 of FIG. 8A), a simulation using the OPC model. Herein, the OPC by the OPC model may not be performed on the first preliminary assist pattern (see 110 of FIG. 8A) and the second preliminary assist pattern (see 120 of FIG. 8A) inserted into the target mask layout (see MA2 of FIG. 8A). Shapes of a first preliminary assist pattern 110s and a second preliminary assist pattern 120s in the mask design image MA3 may be the same as shapes of the first preliminary assist pattern (see 110 of FIG. 8A) and the second preliminary assist pattern (see 120 of FIG. 8A) of the target mask layout (see MA2 of FIG. 8A) before performing the OPC. However, by the OPC model, OPC considering the first preliminary assist pattern (see 110 of FIG. 8A) and the second preliminary assist pattern (see 120 of FIG. 8A) may be performed on the pixel isolation structure pattern (see 100P of FIG. 8A) adjacent to the first preliminary assist pattern (see 110 of FIG. 8A) and the second preliminary assist pattern (see 120 of FIG. 8A) of the target mask layout (see MA2 of FIG. 8A).

Referring to FIG. 10B, the mask design image MA3a, which is OPCed, may be obtained by performing, for the target mask layout (see MA2a of FIG. 9A), a simulation using the OPC model. Herein, the OPC by the OPC model may not be performed on the first preliminary assist pattern (see 112 of FIG. 9A) and the second preliminary assist pattern (see 120 of FIG. 9A) inserted into the target mask layout (see MA2a of FIG. 9A). By the OPC model, OPC considering the first preliminary assist pattern (see 112 of FIG. 9A) and the second preliminary assist pattern (see 120 of FIG. 9A) may be performed on the pixel isolation structure pattern (see 100P of FIG. 9A) adjacent to the first preliminary assist pattern (see 112 of FIG. 9A) and the second preliminary assist pattern (see 120 of FIG. 9A) of the target mask layout (see MA2a of FIG. 9A).

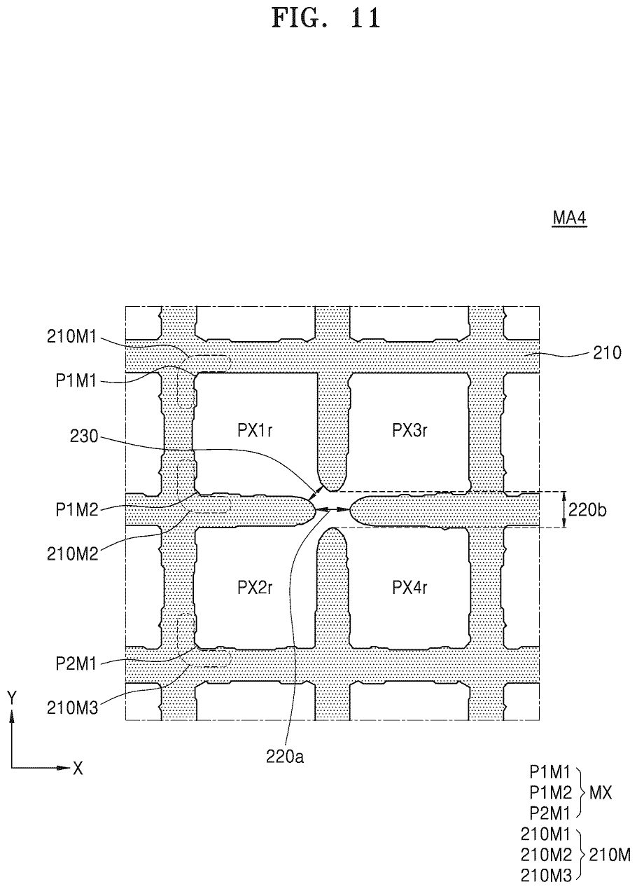

FIG. 11 is a top view illustrating a contour image MA4 in the mask layout design method of FIG. 6. Hereinafter, a description is made with reference to FIG. 6 together.

Referring to FIGS. 6 and 11, after obtaining the plurality of mask design images, a plurality of mask contour images MA4 may be extracted based on the plurality of mask design images in operation P140. The plurality of mask contour images MA4 may be pattern images predicted through a simulation using the plurality of mask design images.

Next, a plurality of target patterns may be selected from among the plurality of preliminary assist patterns based on the plurality of mask contour images MA4 in operation P150. Herein, the selection of the plurality of target patterns may include first selecting at least one mask contour image MA4, in which a first region defining a corner MX of each of the plurality of pixels has a shape close to a right angle such as a rounded right angle or a sharp right angle with a point vertex, from among the plurality of mask contour images MA4. The first region may include a corner formation region 210M. The corner formation region 210M may be a partial region of a pixel isolation structure 210.

In various example embodiments, a corner P1M1 of the first pixel region PX1r in the mask contour image MA4 may be defined by a first corner formation region 210M1. Alternatively or additionally, another corner P1M2 of the first corner formation region 210M1 may be defined by a second corner formation region 210M2.

In some example embodiments, a method of selecting the mask contour image MA4 may include selecting a mask contour image MA4, in which the corner P1M1 of the first pixel region PX1r is formed to be closest to a right angle. Alternatively or additionally, the method of selecting the mask contour image MA4 may include selecting a mask contour image MA4, in which the corner P1M2 of the first pixel region PX1r is formed to be closest to a right angle. In some example embodiments, the method of selecting the mask contour image MA4 may include selecting a mask contour image MA4, in which the corner P2M1 of the second pixel region PX2r is formed to be closest to a right angle.

Alternatively or additionally, the mask contour image MA4 may be selected by considering shapes of all corners of the first to fourth pixel regions PX1r, PX2r, PX3r, and PX4r. Because the mask contour image MA4 is selected by considering the shapes of all the corners of the first to fourth pixel regions PX1r, PX2r, PX3r, and PX4r, the plurality of mask contour images MA4, in which a horizontal width 220a or a vertical width 220b of a central region is different, may be selected. In addition, a diagonal width 230 of a space between any one of the first to fourth pixel regions PX1r, PX2r, PX3r, and PX4r and the central region may also be a considering element of the selection.

Herein, a preliminary assist pattern of the selected at least one mask contour image MA4 may be selected as any one of the plurality of target patterns. For example, any one pattern among a plurality of first preliminary assist patterns (e.g., 110 of FIG. 8A or 112 of FIG. 9A) may be selected as the target pattern. A second preliminary assist pattern (e.g., 120 of FIG. 8A or 9A) may be selected as a set with the first preliminary assist pattern. For example the plurality of target patterns may include the second preliminary assist pattern.

In addition, in some example embodiments, operation P150 may be performed by a method of verifying the first preliminary assist pattern (e.g., 110 of FIG. 8A or 112 of FIG. 9A) by using the mask contour image MA4. Particularly, it may be determined whether a diagonal length of a pixel corner region (e.g., CN of FIG. 9A) of the mask contour image MA4 is less than or equal to a first reference value. If the diagonal length of the pixel corner region is greater than the first reference value, the first preliminary assist pattern may be corrected. Herein, the correction may indicate resizing the first preliminary assist pattern. The diagonal length of the pixel corner region may correspond to a separation distance (Wd of FIG. 4) between pixel structures in a diagonal direction.

Next, a mask may be produced based on the plurality of target mask layouts including the plurality of target patterns in operation P160. The plurality of target mask layouts may be converted into mask tape-out (MTO) design data and produced as the mask. The MTO design data may have a graphic data format used for electronic design automation (EDA) software or the like. For example, the MTO design data may have a data format of one or more of graphic data system II (GDS2), Open Artwork System Interchange Standard (OASIS), or the like.

Thereafter, mask data preparation (MDP) is performed. The MDP may include, for example, one or more of i) format conversion called fracturing, ii) augmentation of a barcode for mechanical reading, a standard mask pattern for inspection, a job deck, and the like, and iii) verification of automatic and manual manners. Herein, the job deck may indicate creating a text file related to arrangement information of multi-mask files, a reference dose, and a series of instructions for an exposure rate or scheme, and the like.

In addition, the format conversion, e.g., fracturing, may indicate or correspond to a process of fracturing the MTO design data for each region to transform the MTO design data into a format for an electron beam (E-beam) writer. The fracturing may include data operations, e.g., one or more of scaling, data sizing, data rotation, pattern reflection, and color inversion. In a conversion process through the fracturing, data may be corrected or improved upon with respect to a lot of errors which may occur in somewhere during a transfer process from design data to an image on a wafer. This data correction process for the system errors is called mask process correction (MPC) and may include one or more of line width adjustment called CD adjustment, a job for increasing pattern arrangement precision, and the like. Therefore, the fracturing may contribute to improvement of the quality of a final mask and also may be a proactive process for the MPC. Herein, the system errors may be caused by distortion occurring in an exposure process, a mask development and etching process, a wafer imaging process, and the like.

The exposure process may be a concept generally containing at least one of electron-beam (E-beam) writing, development, etching, baking, and the like. In addition, before the exposure process, data processing may be performed. The data processing is a kind of a pre-processing process on mask data and may include grammar check of the mask data, exposure time prediction, and the like. Through this MDP, E-beam data for exposing a substrate for a mask to light may be generated.

After the MDP, the substrate for a mask (e.g., chrome-on-glass) is exposed to the light by using the mask data. e.g., the E-beam data. Herein, the exposure may indicate E-beam writing. Herein, the E-beam writing may be performed by, for example, gray writing using a multi-beam mask writer (MBMW). Alternatively or additionally, the E-beam writing may be performed using a variable shape beam (VSB) writer.

After the MDP, a process of transforming the E-beam data into pixel data may be performed before the exposure process. The pixel data is data directly used in real exposure and may include data of a shape to be exposed to the light and data of a dose of an E-beam or light such as UV light allocated to each piece of the data of the shape. Herein, the data of the shape may be or may include bit-map data obtained by transforming shape data that is vector data through rasterization or the like.

After the exposure process, the masking may be completed by performing a series of processes. The series of processes may include, for example, one or more of a development process, an etching process, a cleaning process, and the like. Alternatively or additionally, the series of processes for mask production may include a measurement process and a defect inspection and repair process. Alternatively or additionally, the series of processes may include a pellicle application process. Herein, the pellicle application process may indicate a process of attaching a pellicle to protect a mask from following contamination during distribution of the mask and a usable life time of the mask if it is confirmed through final cleaning and inspection that there are no contamination particles or chemical stains.

A pattern may be formed on the substrate based on the completed mask in operation P170. The pattern corresponding to the pixel isolation structure may be formed on the substrate by performing an exposure process using the completed mask. The pattern formed based on the mask may be the same as shown in FIG. 4.

Referring to FIGS. 6, 4, and 5, a final pattern may be selected from among the plurality of target patterns based on the pattern in operation P180.

For example, the final pattern may be determined based on the central region DCC of the first pixel structure PXT1 and a separation width of the pixel isolation structure DTI. First, when any one of the first protruding portion 102, the second protruding portion 104, the third protruding portion 106, and the fourth protruding portion 108 on the formed final pattern is in contact with another one of the first protruding portion 102, the second protruding portion 104, the third protruding portion 106, and the fourth protruding portion 108, a corresponding target pattern may be excluded from a selection target as the final pattern. Alternatively or additionally, a method of selecting the final pattern may be determined by a size of the central region DCC of the first pixel structure PXT1 formed by the pixel isolation structure DTI.

For example, a target pattern of a mask formed with the least horizontal width DCCx of the central region DCC of the first pixel structure PXT1 may be selected as the final pattern. Alternatively or additionally, a target pattern of a mask formed with the least vertical width DCCy of the central region DCC of the first pixel structure PXT1 may be selected as the final pattern. Alternatively or additionally, a target pattern of a mask formed with the least horizontal width DCCx and the least vertical width DCCy of the central region DCC of the first pixel structure PXT1 may be selected as the final pattern.

In some example embodiments, operation P180 may be performed by a method of verifying a second preliminary assist pattern based on the pattern. For example, the verification may be determined whether regions of the pixel isolation structure DTI are in contact with each other in the central region DCC of the first pixel structure PXT1 of the pattern. For example, the verification determined whether any one of the first protruding portion 102, the second protruding portion 104, the third protruding portion 106, and the fourth protruding portion 108 is in contact with another one of the first protruding portion 102, the second protruding portion 104, the third protruding portion 106, and the fourth protruding portion 108. If it is determined that the pixel isolation structure DTI is in a contact state in the central region DCC, a size of the second preliminary assist pattern 120 may be corrected or at least partly corrected. If it is determined that regions of the pixel isolation structure DTI are separated from each other in the central region DCC, the second preliminary assist pattern 120 having the least separation width of the pixel isolation structure DTI may be selected as the final pattern.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various inventive concepts have been particularly shown and described with reference to various example embodiments thereof, it will be understood that various changes in form and details may be made therein without departing from the spirit and scope of the following claims. Additionally, example embodiments are not necessarily mutually exclusive with one another. For example, some example embodiments may include one or more features described with reference to one or more drawings and may also include one or more other features described with reference to one or more other drawings.

What is claimed is:

1. A mask layout design method comprising:
designing a preliminary mask layout;
designing a plurality of target mask layouts by inserting a plurality of preliminary assist patterns into the preliminary mask layout;
generating an optical proximity correction (OPC) model based on the plurality of target mask layouts;
obtaining a plurality of mask design images by performing a simulation using the OPC model;
extracting a plurality of mask contour images based on the plurality of mask design images;
selecting a plurality of target patterns from among the plurality of preliminary assist patterns based on the plurality of mask contour images;
producing a mask based on the plurality of target mask layouts comprising the plurality of target patterns;
forming a real pattern on a substrate based on the mask; and
selecting a final pattern from among the plurality of target patterns based on the formed real pattern, wherein
the preliminary mask layout includes a mask layout defining a pixel isolation structure that isolates a plurality of pixels, and
the preliminary assist pattern has at least one of a cross or rectangular shape in plan view.

2. The mask layout design method of claim 1, wherein
the plurality of preliminary assist patterns comprise a first preliminary assist pattern having any one of the cross and rectangular shapes and a second preliminary assist pattern having the cross shape, and
a size of the first preliminary assist pattern is less than a size of the second preliminary assist pattern.

3. The mask layout design method of claim 2, wherein
at least eight first preliminary assist patterns are inserted into the preliminary mask layout, and
the first preliminary assist patterns are inserted into a pixel corner region formed at an outer side of each of the plurality of pixels formed in the preliminary mask layout.

4. The mask layout design method of claim 2, wherein the second preliminary assist pattern is inserted into a central region of the preliminary mask layout.

5. The mask layout design method of claim 2, wherein a horizontal width of the first preliminary assist pattern is less than a horizontal width of a pixel corner region formed at an outer side of each of the plurality of pixels formed in the preliminary mask layout.

6. The mask layout design method of claim 2, wherein the first preliminary assist pattern is inserted with a mask tone that is different from a mask tone of the preliminary mask layout.

7. The mask layout design method of claim 2, wherein
the designing of the preliminary mask layout comprises designing the preliminary mask layout based on a design rule of the pixel isolation structure, and
the second preliminary assist pattern among the plurality of preliminary assist patterns has a larger size than that of the design rule.

8. The mask layout design method of claim 2, wherein the selecting of the final pattern comprises,
selecting the final pattern based on a formed shape of the pixel isolation structure, and
in response to regions of the pixel isolation structure being in contact with each other in a central region of the plurality of pixels, a target pattern on which the real pattern is formed based is excluded from a selection target of the final pattern.

9. The mask layout design method of claim 8, wherein the OPC model performs OPC on the plurality of target mask layouts by considering regions into which the plurality of preliminary assist patterns are inserted.

10. The mask layout design method of claim 1, wherein the selecting of the plurality of target patterns comprises,
selecting at least one mask contour image having a shape in which a first region defining corners of the plurality of pixels includes at least one of a right angle or a right angle partially rounded, from among the plurality of mask contour images, and
a preliminary assist pattern of the selected at least one mask contour image is selected as any one of the plurality of target patterns.

11. The mask layout design method of claim 1, wherein
the obtaining of the plurality of mask design images by performing the simulation using the OPC model comprises performing OPC on each of the plurality of target mask layouts by using the OPC model, and
the OPC model does not perform the OPC on the plurality of preliminary assist patterns.

12. A mask layout design method comprising:
designing a preliminary mask layout based on a design rule;
designing a target mask layout by inserting a first preliminary assist pattern and a second preliminary assist pattern into the preliminary mask layout;
verifying the first preliminary assist pattern by using the target mask layout;
producing a mask based on the target mask layout;
forming a real pattern on a substrate based on the mask; and
verifying the second preliminary assist pattern based on the real pattern, wherein
the preliminary mask layout includes a mask layout defining a pixel isolation structure isolating a plurality of pixels, and
the first preliminary assist pattern is inserted into a pixel corner region of the preliminary mask layout, and the second preliminary assist pattern is inserted into a central region of the preliminary mask layout.

13. The mask layout design method of claim 12, wherein the verifying of the first preliminary assist pattern comprises:
extracting a mask contour image by using the target mask layout; and
determining whether a diagonal length of a pixel corner region of the mask contour image is less than or equal to a first reference value.

14. The mask layout design method of claim 13, wherein, the first preliminary assist pattern is corrected in response to the diagonal length of the pixel corner region being greater than the first reference value.

15. The mask layout design method of claim 12, wherein the verifying of the second preliminary assist pattern based on the real pattern comprises,
determining whether regions of the pixel isolation structure are in contact with each other in a central region of the real pattern, and
the second preliminary assist pattern is corrected in response to determining that the regions of the pixel isolation structure are in contact with each other.

16. The mask layout design method of claim 15, wherein the verifying of the second preliminary assist pattern based on the real pattern comprises,
selecting, as a final pattern, the second preliminary assist pattern having the least separation width of the pixel isolation structure in response to determining that the regions of the pixel isolation structure are separated from each other in the central region.

17. The mask layout design method of claim 12, wherein the first preliminary assist pattern has a feature size less than a size of a sub-resolution assist feature (SRAF) pattern.

18. A mask layout design method comprising:
designing a preliminary mask layout;
designing a plurality of target mask layouts by inserting a plurality of preliminary assist patterns into the preliminary mask layout;
generating an optical proximity correction (OPC) model based on the plurality of target mask layouts;
obtaining a plurality of mask design images by using the OPC model to perform OPC on each of the plurality of target mask layouts;
extracting a plurality of mask contour images based on the plurality of mask design images;
selecting a plurality of target patterns from among the plurality of preliminary assist patterns based on the plurality of mask contour images;
producing a mask based on the plurality of target mask layouts comprising the plurality of target patterns;
forming a real pattern on a substrate based on the mask; and
selecting a final pattern from among the plurality of target patterns based on the real pattern, wherein
the preliminary mask layout includes a mask layout defining a pixel isolation structure isolating a plurality of pixels, and
the preliminary assist pattern comprises a first preliminary assist pattern and a second preliminary assist pattern, the first preliminary assist pattern is inserted into a pixel corner region of the mask layout, and the second preliminary assist pattern is formed in a central region of the mask layout.

19. The mask layout design method of claim 18, wherein the OPC model does not perform the OPC on the plurality of preliminary assist patterns but performs the OPC on the plurality of target mask layouts by considering regions into which the plurality of preliminary assist patterns are inserted.

20. The mask layout design method of claim 18, wherein
the first preliminary assist pattern has features having a greater size than those of a sub-resolution assist feature (SRAF) pattern,
the second preliminary assist pattern has features having a greater size than that in a design rule, and
any one of the plurality of target mask layouts comprises at least eight first preliminary assist patterns and at least one second preliminary assist pattern.
